(19) United States
(12) Patent Application Publication
(10) Pub. No.: US 2026/0162696 A1
(43) Pub. Date: Jun. 11, 2026

(54) MEMORY DEVICES AND MEMORY SYSTEMS CONTROLLING OPERATING VOLTAGES

(71) Applicant: SK hynix Inc., Icheon-si Gyeonggi-do (KR)

(72) Inventors: Hyeon Jin YANG, Icheon-si Gyeonggi-do (KR); Tae Ho KIM, Icheon-si Gyeonggi-do (KR); Dong Ju YANG, Icheon-si Gyeonggi-do (KR); Se Jun HAN, Icheon-si Gyeonggi-do (KR)

(73) Assignee: SK hynix Inc., Icheon-si Gyeonggi-do (KR)

(21) Appl. No.: 19/085,722

(22) Filed: Mar. 20, 2025

(30) Foreign Application Priority Data
Dec. 10, 2024 (KR) 10-2024-0183143

(51) Int. Cl. G11C 5/14

(52) U.S. Cl. CPC G11C 5/14

(57) ABSTRACT

A memory device includes a base die and a plurality of core dies stacked over an interposer. The base die receives and operates at an input/output power voltage, and each of the plurality of core dies receives a power supply voltage through the base die to generate a peripheral voltage at a lower voltage level than the power supply voltage and operates at the peripheral voltage.

### CROSS-REFERENCE TO RELATED APPLICATIONS

The present application claims priority under 35 U.S.C § 119(a) to Korean Application No. 10-2024-0183143, filed in the Korean Intellectual Property Office on Dec. 10, 2024, the entire contents of which application is incorporated herein by reference.

### BACKGROUND

### 1. Technical Field

The present disclosure relates to memory devices and memory systems including but not limited to operating voltages for memory devices.

### 2. Related Art

Stack memory systems such as high bandwidth memory (HBM) devices are used in a wide range of applications due to their high bandwidth and energy efficiency. Unlike conventional memory systems that use parallel data buses, stack memory systems include a stack memory device including a base die and a plurality of core dies interconnected by through silicon vias (TSVs). The stack memory device includes a physical interface, such as a physical layer for communication with a processor. The physical layer is designed for high-speed data transmission and efficient communication.

### SUMMARY

The present disclosure describes a memory system that may include an interposer disposed over a substrate, and a memory device and a processor disposed over the interposer and connected through wiring inside the interposer. The memory device may include a base die and a plurality of core dies stacked over the interposer. The base die may operate at an input/output power voltage, and each of the plurality of core dies may generate and operate at a peripheral voltage. Each of the plurality of core dies may receive a power supply voltage through the base die to generate a peripheral voltage at a lower voltage level than the power supply voltage and operate at the peripheral voltage.

The present disclosure describes a memory device including a base die configured to receive and operate at an input/output power voltage, and a plurality of core dies stacked over the base die. Each of the plurality of core dies may receive a power supply voltage through the base die to generate a peripheral voltage at a lower voltage level than the input/output power voltage and operate at the peripheral voltage.

The present disclosure describes a method of controlling an operating voltage, including pull-up driving a peripheral voltage supplied to a core die to a power supply voltage when a power boot-up signal is activated and pull-down driving the peripheral voltage to a ground voltage when the power boot-up signal is deactivated. The power boot-up signal is activated according to a power supply voltage until a boot-up operation is terminated, and deactivated in synchronization with a time when the boot-up operation is terminated.

A memory device may include a core die configured to comprise a plurality of peripheral voltage control circuits. Each of peripheral voltage control circuits is configured to pull-up drive and pull-down drive to generate a peripheral voltage. The core die operates at the peripheral voltage, receives a power supply voltage, and generates the peripheral voltage at a lower voltage level than the power supply voltage.

### BRIEF DESCRIPTION OF THE DRAWINGS

FIG. 1 illustrates a memory system according to an embodiment of the present disclosure.

FIG. 2 illustrates a core die according to an embodiment of the present disclosure.

FIG. 3 illustrates a peripheral voltage control circuit according to an embodiment of the present disclosure.

FIG. 4 illustrates an embodiment of a pull-up driving circuit according to an embodiment of the present disclosure.

FIG. 5 illustrates an embodiment of a pull-down driving circuit according to an embodiment of the present disclosure.

FIG. 6 illustrates an embodiment of a leakage switching signal generation circuit according to an embodiment of the present disclosure.

FIG. 7 illustrates an embodiment of a leakage driving circuit according to an embodiment of the present disclosure.

FIG. 8 is a timing diagram illustrating operation of a peripheral voltage control circuit according to an embodiment of the present disclosure.

FIG. 9 illustrates a peripheral voltage control circuit according to an embodiment of the present disclosure.

FIG. 10 illustrates an embodiment of a first pull-down driving circuit according to an embodiment of the present disclosure.

FIG. 11 illustrates an embodiment of a first leakage switching signal generation circuit according to an embodiment of the present disclosure.

FIG. 12 illustrates an embodiment of a second pull-down driving circuit according to an embodiment of the present disclosure.

FIG. 13 illustrates an embodiment of a second leakage switching signal generation circuit according to an embodiment of the present disclosure.

FIG. 14 is a timing diagram illustrating operation of a peripheral voltage control circuit according to an embodiment of the present disclosure.

### DETAILED DESCRIPTION

The cross-hatching throughout the figures illustrates corresponding or similar areas between the figures rather than indicating the materials associated with the areas.

Terms such as “first” and “second” are used to distinguish between various elements and do not imply size, order, priority, quantity, or importance of the elements. For example, a first element may be named as a second element in one example, and the second element may be named as a first element in another example.

When one component is identified as “connected” to another component, the components may be connected directly or through an intervening component between the components. When two components are identified as “directly connected,” one component is directly connected to the other component without an intervening component between the two components.

A logic “high” level and a logic “low” level may be used to describe logic levels of electric signals. A signal at a logic high level is distinguished from a signal at a logic low level. For example, when a signal at a first voltage corresponds to a signal at a logic high level, a signal at a second voltage corresponds to a signal at a logic low level. In an embodiment, the logic high level may be a voltage level that is higher than a voltage level of the logic low level. Logic levels of signals may be different or opposite according to the embodiments. For example, a signal at a logic high level in one embodiment may be at a logic low level in another embodiment, and a signal at a logic low level in one embodiment may be at a logic high level in another embodiment.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

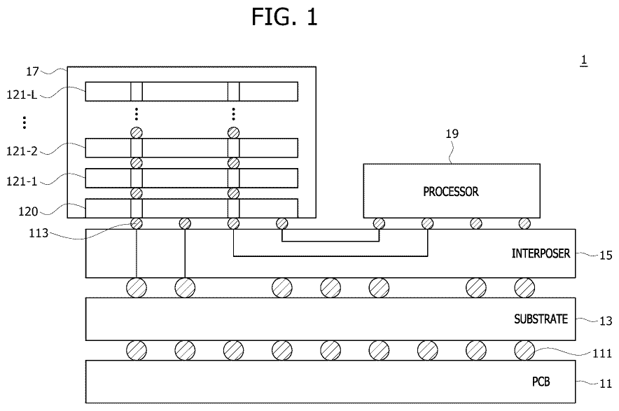

FIG. 1 illustrates a memory system 1 according to an embodiment of the present disclosure.

As shown in FIG. 1, the memory system 1 includes a printed circuit board (PCB) 11, a substrate 13, an interposer 15, a memory device 17, and a processor 19.

The printed circuit board 11 connects various electronic components to each other to form an electronic circuit (not shown). The electronic circuit includes the memory system 1. A copper (Cu) layer, a solder mask, a silk screen, and so forth are formed on the printed circuit board 11. A circuit path that transmits or transfers signals or power is formed in the copper (Cu) layer. The solder mask prevents damage to the circuit and protects a specific region where components are soldered. The silk screen indicates location or information for the electronic components as characters or symbols printed on a surface of the printed circuit board 11.

The substrate 13 is disposed over the printed circuit board 11 with bump pads in between, for example, bump pads 111 that mechanically support the interposer 15, the memory device 17, and the processor 19. The substrate 13 functions as a physical base for the printed circuit board 11 and is an insulator. The substrate 13 may include materials such as FR4 that is an insulator made of fiberglass and epoxy resin, ceramics that can withstand high temperatures, have appropriate thermal conductivity properties, and are used in high-frequency circuits, polyimide that is used as a basic material for flexible PCBs due to flexible characteristics, and the like.

The interposer 15 is disposed over the substrate 13 with bump pads in between and includes wiring that connects electronic components, for example, the memory device 17 and the processor 19, that have form factors or pin arrangements do not match or have different spacing. The interposer 15 converts signals for communication between different interfaces, for example, DDR, HBM, and PCIe.

The memory device 17 is disposed over the interposer 15 with pads in between, for example, micro-bumps 113. The memory device 17 stores data received from the processor 19 or outputs the stored data to the processor 19 under control of the processor 19. The memory device 17 includes a base die 120 and a plurality of core dies 121-1 to 121-L, where L is an integer greater than 1. The core dies 121-1 to 121-L are stacked over the base die 120 with micro-bump pads in between. The base die 120 and the core dies 121-1 to 121-L are vertically connected to each other using through-vias and micro-bump pads. The base die 120 controls efficient data transmission between the processor 19 and the core dies 121-1 to 121-L. The base die 120 receives input/output power voltage (voltage drain drain for IO also referred to as output stage drain power voltage) VDDQ as an operating voltage utilized during operation of internal circuits included in the base die 120. The base die 120 receives the input/output power voltage VDDQ from the printed circuit board 11 through the substrate 13 and the interposer 15. The input/output power voltage VDDQ is a voltage supplied to buffers that transmit data and is distinguished or different from the power supply voltage VDD. The core dies 121-1 to 121-L use a peripheral voltage VPERI as an operating voltage during operation of the internal circuits included in the core dies 121-1 to 121-L. The core dies 121-1 to 121-L generate the peripheral voltage VPERI from the power supply voltage VDD received through the base die 120. The core dies 121-1 to 121-L generate the peripheral voltage VPERI at a lower voltage level than the power supply voltage VDD and use the peripheral voltage VPERI as an operating voltage. Each of the core dies 121-1 to 121-L includes a plurality of channel regions, for example, eight channel regions or sixteen channel regions that operate independently. Each of the plurality of channel regions is allocated with a channel operating independently to receive or transmit data. The number L of core dies 121-1 to 121-L may be four, eight, twelve, sixteen, and so forth. For example, when each of the core dies 121-1 to 121-12 has eight channels, the core dies 121-1 to 121-4, the core dies 121-5 to 121-8, and the core dies 121-9 to 121-12 each include thirty-two channel regions, and transmit and receive data with the processor 19 in units of a rank including thirty-two channels.

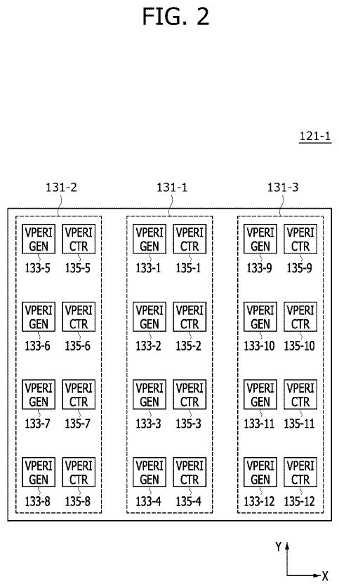

FIG. 2 illustrates a core die 121-1 according to an embodiment of the present disclosure.

As shown in FIG. 2, the core die 121-1 includes a first central region 131-1, a first edge region 131-2, and a second edge region 131-3. The first central region 131-1 is located at a center of the core die 121-1. The first edge region 131-2 is located to a first side of the first central region 131-1 in a direction opposite to the first direction X, and the second edge region 131-3 is located to a second side of the first central region 131-1 in the first direction X. Although each of the first central region 131-1, the first edge region 131-2, and the second edge region 131-3 are illustrated as longer in a second direction Y than in the first direction X in this example, and the present disclosure is not limited to this example.

A first peripheral voltage generation circuit 133-1 to a fourth peripheral voltage generation circuit 133-4 and a first peripheral voltage control circuit 135-1 to a fourth peripheral voltage control circuit 135-4 are located in the first central region 131-1. The peripheral voltage generation circuits 133-1 to 133-4 are spaced apart by the same interval in the second direction Y. The peripheral voltage control circuits 135-1 to 135-4 are spaced apart by the same interval in the second direction Y. The first peripheral voltage control circuit 135-1 is positioned to a side of the first peripheral voltage generation circuit 133-1 in the first direction X and controls a level of the peripheral voltage VPERI generated by the first peripheral voltage generation circuit 133-1. The second peripheral voltage control circuit 135-2 is positioned to a side of the second peripheral voltage generation circuit 133-2 in the first direction X and controls the level of the peripheral voltage VPERI generated by the second peripheral voltage generation circuit 133-2. The third peripheral voltage control circuit 135-3 is positioned to a side of the third peripheral voltage generation circuit 133-3 in the first direction X and controls the level of the peripheral voltage VPERI generated by the third peripheral voltage generation circuit 133-3. The fourth peripheral voltage control circuit 135-4 is positioned to a side of the fourth peripheral voltage generation circuit 133-4 in the first direction X and controls the level of the peripheral voltage VPERI generated by the fourth peripheral voltage generation circuit 133-4.

A fifth peripheral voltage generation circuit 133-5 to an eighth peripheral voltage generation circuit 133-8 and a fifth peripheral voltage control circuit 135-5 to an eighth peripheral voltage control circuits 135-8 are located in the first edge region 131-2. The peripheral voltage generation circuits 133-5 to 133-8 are spaced apart by the same interval in the second direction Y. The peripheral voltage control circuits 135-5 to 135-8 are spaced apart by the same interval in the second direction Y. The fifth peripheral voltage control circuit 135-5 is positioned to a side of the fifth peripheral voltage generation circuit 133-5 in the first direction X and controls the level of the peripheral voltage VPERI generated by the fifth peripheral voltage generation circuit 133-5. The sixth peripheral voltage control circuit 135-6 is positioned to a side of the sixth peripheral voltage generation circuit 133-6 in the first direction X and controls the level of the peripheral voltage VPERI generated by the sixth peripheral voltage generation circuit 133-6. The seventh peripheral voltage control circuit 135-7 is positioned to a side of the seventh peripheral voltage generation circuit 133-7 in the first direction X and controls the level of the peripheral voltage VPERI generated by the seventh peripheral voltage generation circuit 133-7. The eighth peripheral voltage control circuit 135-8 is positioned to a side of the eighth peripheral voltage generation circuit 133-8 in the first direction X and controls the level of the peripheral voltage VPERI generated by the eighth peripheral voltage generation circuit 133-8.

A ninth peripheral voltage generation circuit 133-9 to a twelfth peripheral voltage generation circuit 133-12 and a ninth peripheral voltage control circuit 135-9 to twelfth peripheral voltage control circuit 135-12 are positioned in the second edge region 131-3. The peripheral voltage generation circuits 133-9 to 133-12 are spaced apart by the same interval in the second direction Y. The peripheral voltage control circuits 135-9 to 135-12 are spaced apart by the same interval in the first direction Y. The ninth peripheral voltage control circuit 135-9 is positioned to a side of the ninth peripheral voltage generation circuit 133-9 in the first direction X and controls the level of the peripheral voltage VPERI generated by the ninth peripheral voltage generation circuit 133-9. The tenth peripheral voltage control circuit 135-10 is positioned to a side of the tenth peripheral voltage generation circuit 133-10 in the first direction X and controls the level of the peripheral voltage VPERI generated by the tenth peripheral voltage generation circuit 133-10. The eleventh peripheral voltage control circuit 135-11 is positioned to a side of the eleventh peripheral voltage generation circuit 133-11 in the first direction X and controls the level of the peripheral voltage VPERI generated by the eleventh peripheral voltage generation circuit 133-11. The twelfth peripheral voltage control circuit 135-12 is positioned to a side of the twelfth peripheral voltage generation circuit 133-12 in the first direction X and controls the level of the peripheral voltage VPERI generated by the twelfth peripheral voltage generation circuit 133-12.

Each of the core dies 121-2 to 121-L shown in FIG. 1 may include a central region and two edge regions, similar to the core die 121-1. The thirty-two channels included in four core dies among the core dies 121-1 to 121-L are classified into one rank, and the core dies 121-1 to 121-L exchange data with the processor 19 through the thirty-two channels constituting the one rank.

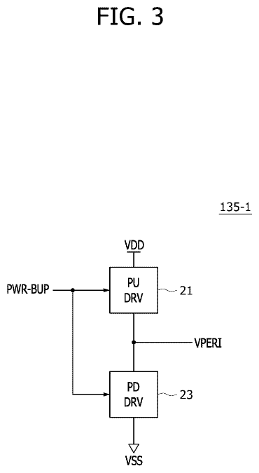

FIG. 3 illustrates a peripheral voltage control circuit 135-1 according to an embodiment of the present disclosure, for example, as shown in FIG. 2.

As shown in FIG. 3, the peripheral voltage control circuit 135-1 includes a pull-up driving circuit (PU DRV) 21 and a pull-down driving circuit (PD DRV) 23.

The pull-up driving circuit 21 pull-up drives a peripheral voltage VPERI based on a power boot-up signal PWR-BUP. The power boot-up signal PWR-BUP is activated according to a power supply voltage VDD during a power-up time period and is deactivated in synchronization with the termination of a boot-up operation. The power-up time period is a time period from a time when the power supply voltage VDD is applied to the memory device 17 of FIG. 1 at 0 V to a time when the power supply voltage VDD reaches a preset voltage level in this example. The boot-up operation refers to an initialization process of the memory system 1 of FIG. 1. The initialization process of the memory system 1 includes setting memory channels, setting an operating frequency of a clock signal for timing of signals, setting a voltage level of an operating voltage including the peripheral voltage VPERI, adjusting parameters for various operations, and the like. Pull-up driving the peripheral voltage VPERI includes driving the peripheral voltage VPERI to the power supply voltage VDD. The pull-up driving circuit 21 pull-up drives the peripheral voltage VPERI during the time period in which the power boot-up signal PWR-BUP is activated. The pull-up driving circuit 21 pull-up drives the peripheral voltage VPERI to the power supply voltage VDD during a time period in which the boot-up operation is performed from a time when the power supply voltage VDD reaches a preset voltage level.

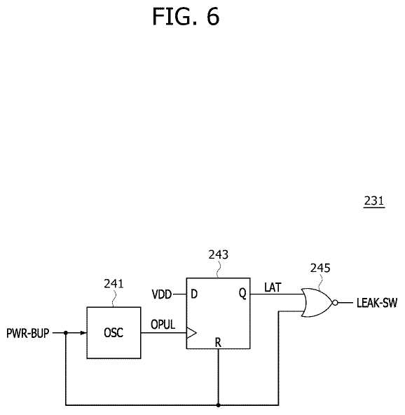

The pull-down driving circuit 23 pull-down drives the peripheral voltage VPERI based on the power boot-up signal PWR-BUP. Pull-down driving the peripheral voltage VPERI includes driving the peripheral voltage VPERI to a ground voltage VSS, for example, when the charge or voltage at a peripheral voltage VPERI terminal is discharged. The peripheral voltage VPERI terminal includes a terminal to which the peripheral voltage VPERI is electrically connected. The pull-down driving circuit 23 pull-down drives the peripheral voltage VPERI during a driving time period after the boot-up operation is terminated and when the power boot-up signal PWR-BUP is deactivated. The driving time period may be predetermined or preset. The driving time period is established based on a cycle of an oscillating pulse, for example, OPUL of FIG. 6, generated from an oscillator, for example, OSC of FIG. 6. The pull-down driving circuit 23 pull-down drives the peripheral voltage VPERI when the boot-up operation is terminated such that the voltage level of the peripheral voltage VPERI quickly reaches a target voltage level.

Each of the peripheral voltage control circuits 135-2 to 135-12 of FIG. 2 may include a configuration for pull-up driving and pull-down driving the peripheral voltage VPERI generated from each of the second peripheral voltage generation circuit 133-2 to the twelfth peripheral voltage generation circuit to 133-12 in the same manner as the peripheral voltage control circuit 135-1.

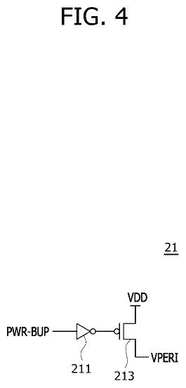

FIG. 4 illustrates an embodiment of a pull-up driving circuit 21 according to an embodiment of the present disclosure, for example, as shown in FIG. 3.

As shown in FIG. 4, the pull-up driving circuit 21 includes an inverter 211 and a PMOS transistor 213. The inverter 211 inversely buffers the power boot-up signal PWR-BUP and outputs an inversely buffered signal of the power boot-up signal PWR-BUP. The PMOS transistor 213 is turned on based on an output signal of the inverter 211 and operates as a pull-up device that pull-up drives the peripheral voltage VPERI. The inverter 211 inversely buffers the power boot-up signal PWR-BUP activated at a logic high level to output an inversely buffered signal of the power boot-up signal PWR-BUP at a logic low level during a time period in which the boot-up operation is performed from a time when the power supply voltage VDD reaches a preset voltage level. The PMOS transistor 213 is turned on to pull-up drive the peripheral voltage VPERI when the output signal of the inverter 211 at a logic low level. The pull-up driving circuit 21 receives the power boot-up signal PWR-BUP that is activated at a logic high level to pull-up drive the peripheral voltage VPERI to the power supply voltage VDD during the boot-up operation time period from the time when the power supply voltage VDD reaches the preset voltage level.

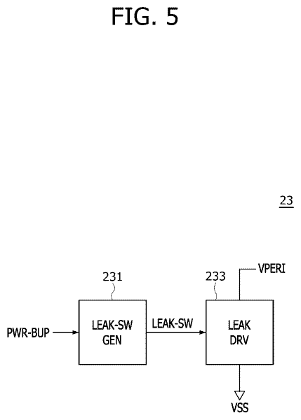

FIG. 5 illustrates an embodiment of a pull-down driving circuit 23 according to an embodiment of the present disclosure, for example, as shown in FIG. 3.

As shown in FIG. 5, the pull-down driving circuit 23 includes a leakage switching signal generation circuit (LEAK-SW GEN) 231 and a leakage driving circuit (LEAK DRV) 233.

The leakage switching signal generation circuit 231 generates a leakage switching signal LEAK-SW for pull-down driving the peripheral voltage VPERI during a driving time period after the boot-up operation is terminated based on the power boot-up signal PWR-BUP. The leakage switching signal generation circuit 231 receives the power boot-up signal PWR-BUP that is deactivated after the boot-up operation is terminated and generates an oscillating pulse, for example, OPUL of FIG. 6, which is a cyclic signal. The leakage switching signal generation circuit 231 generates the leakage switching signal LEAK-SW that is activated to pull-down drive the peripheral voltage VPERI during the driving time period based on a cycle or frequency of the oscillating pulse.

The leakage driving circuit 233 is electrically connected to the leakage switching signal generation circuit 231 and receives the leakage switching signal LEAK-SW from the leakage switching signal generation circuit 231. The leakage driving circuit 233 pull-down drives the peripheral voltage VPERI based on the leakage switching signal LEAK-SW. The leakage driving circuit 233 receives the leakage switching signal LEAK-SW that is activated during the driving time period after the boot-up operation is terminated to pull-down drive the peripheral voltage VPERI.

FIG. 6 illustrates an embodiment of a leakage switching signal generation circuit 231 according to an embodiment of the present disclosure, for example, as shown in FIG. 5.

As shown in FIG. 6, the leakage switching signal generation circuit 231 includes an oscillator (OSC) 241, a latch 243, and a logic device 245.

The oscillator 241 generates an oscillating pulse OPUL based on a power boot-up signal PWR-BUP. The oscillator 241 generates the oscillating pulse OPUL when the power boot-up signal PWR-BUP that is deactivated is received after the boot-up operation is terminated. The oscillating pulse OPUL is a cyclic signal, and a cycle of the oscillating pulse OPUL is, for example, 1 ms, and the present disclosure is not limited to this example.

The latch 243 is electrically connected to the oscillator 241 and receives the oscillating pulse OPUL from the oscillator 241. The latch 243 generates a latch signal LAT that is activated when the oscillating pulse OPUL is generated. The latch 243 latches the power supply voltage VDD when the oscillating pulse OPUL is at a logic high level at a time when the driving time period elapses after the boot-up operation is terminated, thereby generating the latch signal LAT that is activated at a logic high level. The driving time period is half a cycle of the oscillating pulse OPUL, for example, 0.5 ms, and the present disclosure is not limited to this example. The latch 243 initializes the latch signal LAT based on the power boot-up signal PWR-BUP. The latch 243 initializes the latch signal LAT at a logic low level when the power boot-up signal PWR-BUP activated at a logic high level is received during a time period during which the boot-up operation is performed from the time when the power supply voltage VDD reaches a preset voltage level.

The logic device 245 is electrically connected to the latch 243 and receives the latch signal LAT from the latch 243. The logic device 245 receives the latch signal LAT and the power boot-up signal PWR-BUP, performs a NOR operation, and generates the leakage switching signal LEAK-SW. The logic device 245 receives the latch signal LAT and the power boot-up signal PWR-BUP that are both deactivated during the driving time period after the boot-up operation is terminated and generates the leakage switching signal LEAK-SW that is activated.

When the power boot-up signal PWR-BUP activated at a logic high level is received during a time period during which the boot-up operation is performed from the time when the power supply voltage VDD reaches a preset voltage level, the latch 243 initializes the latch signal LAT at a logic low level, and the logic device 245 generates the leakage switching signal LEAK-SW deactivated at a logic low level. After the boot-up operation is terminated and the power boot-up signal PWR-BUP deactivated at a logic low level is received, the oscillator 241 generates the oscillating pulse OPUL. During the driving time period, which is a time period after the boot-up operation is terminated to the time the oscillating pulse OPUL is generated at a logic high level, the latch signal LAT is maintained at a logic low level and the power boot-up signal PWR-BUP is maintained in a deactivated state at a logic low level. Accordingly, the logic device 245 generates the leakage switching signal LEAK-SW activated at a logic high level. Because the latch 243 latches the power supply voltage VDD to generate the latch signal LAT at a logic high level at the time when the oscillating pulse OPUL is generated at a logic high level and the driving time period is terminated, the logic device 245 generates the leakage switching signal LEAK-SW deactivated at a logic low level. The leakage switching signal generation circuit 231 receives the power boot-up signal PWR-BUP that is deactivated after the boot-up operation is terminated to generate the oscillating pulse OPUL, which is a cyclic signal, and generates the leakage switching signal LEAK-SW activated at a logic high level to pull-down drive the peripheral voltage VPERI during the driving time period based on the cycle of the oscillating pulse.

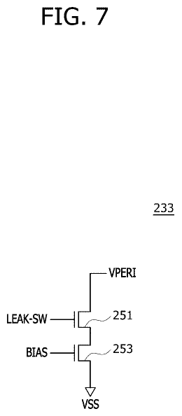

FIG. 7 illustrates an embodiment of a leakage driving circuit 233 according to an embodiment of the present disclosure, for example, as shown in FIG. 5.

As shown in FIG. 7, the leakage driving circuit 233 includes transistors 251 and 253 that are connected in series between a peripheral voltage VPERI terminal and a ground voltage VSS terminal. The ground voltage VSS terminal includes a terminal to which the ground voltage VSS is electrically connected. The NMOS transistor 251 operates as a driving device that receives the leakage switching signal LEAK-SW and is turned on. The NMOS transistor 251 operates as a bias device that receives a bias voltage BIAS and maintains a turn-on state. The leakage driving circuit 233 receives the leakage switching signal LEAK-SW that is activated and pull-down drives the peripheral voltage VPERI during a driving time period after the boot-up operation is terminated.

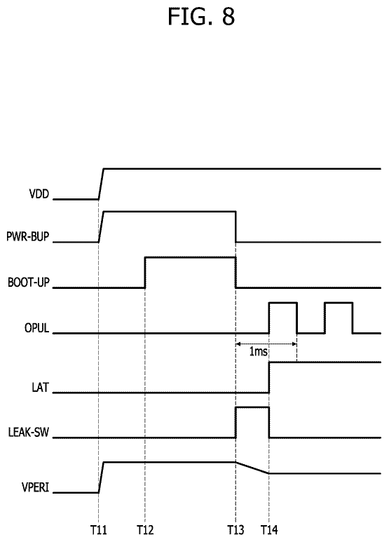

FIG. 8 is a timing diagram illustrating operation of a peripheral voltage control circuit 135-1, for example, as shown in FIG. 1 and FIG. 3.

At time T11, when a power supply voltage VDD is applied to a memory device 17 of FIG. 1, a voltage level of a power boot-up signal PWR-BUP rises together with the power supply voltage VDD. When the power supply voltage VDD reaches a preset voltage level, the power boot-up signal PWR-BUP is activated at a logic high level. A pull-up driving circuit 21 of FIG. 1 receives the power boot-up signal PWR-BUP activated at the logic high level to pull-up drive a peripheral voltage VPERI to the power supply voltage VDD.

At time T12, a boot-up operation is initiated. During the boot-up operation, an initialization process including setting memory channels, setting an operating frequency of a clock signal for timing of signals, setting a voltage level of an operating voltage including the peripheral voltage VPERI, adjusting parameters for various operations, and the like. During the boot-up operation, the power boot-up signal PWR-BUP remains activated at a logic high level. The peripheral voltage VPERI remains in a pull-up driven state to the power supply voltage VDD during the boot-up operation.

At time T13, after the boot-up operation is terminated, the power boot-up signal PWR-BUP is deactivated at a logic low level. The oscillator 241 generates an oscillating pulse OPUL in response to receiving the power boot-up signal PWR-BUP deactivated at a logic low level to.

At time T14, when the oscillating pulse OPUL is generated at a logic high level, a leakage switching signal generation circuit 231 shown in FIG. 5 generates a leakage switching signal LEAK-SW that is activated at a logic high level during a driving time period T13 to T14 after the boot-up operation is terminated to a time when the oscillating pulse OPUL is generated at the logic high level. A leakage driving circuit 233 shown in FIG. 5 pull-down drives the peripheral voltage VPERI according to the leakage switching signal LEAK-SW activated during the driving time period T13 to T14. At time T14, the peripheral voltage VPERI is pull-down driven during the driving time period, such that the peripheral voltage VPERI quickly reaches a target voltage level.

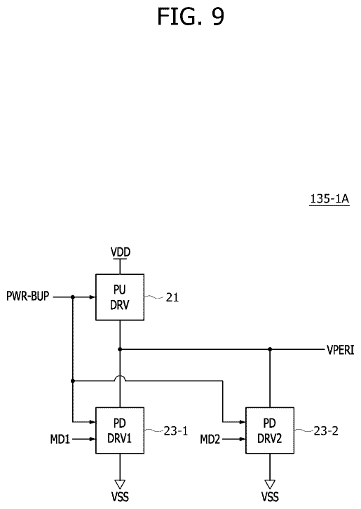

FIG. 9 illustrates a peripheral voltage control circuit 135-1A according to an embodiment of the present disclosure.

As shown in FIG. 9, the peripheral voltage control circuit 135-1A includes a pull-up driving circuit (PU DRV) 21, a first pull-down driving circuit (PD DRV1) 23-1, and a second pull-down driving circuit (PD DRV2) 23-2.

The pull-up driving circuit 21 pull-up drives a peripheral voltage VPERI based on a power boot-up signal PWR-BUP. The pull-up driving circuit 21 pull-up drives the peripheral voltage VPERI during a time period during which the power boot-up signal PWR-BUP is activated. The pull-up driving circuit 21 pull-up drives the peripheral voltage VPERI to the power supply voltage VDD during the time period during which the boot-up operation is performed from a time when the power supply voltage VDD reaches a preset voltage level.

The first pull-down driving circuit 23-1 pull-down drives the peripheral voltage VPERI using a first driving force based on the power boot-up signal PWR-BUP and a first mode signal MD1. The first mode signal MD1 is activated to pull-down drive the peripheral voltage VPERI using the first driving force. The first pull-down driving circuit 23-1 pull-down drives the peripheral voltage VPERI using the first driving force during a driving time period after the boot-up operation is terminated and the power boot-up signal PWR-BUP is deactivated while the first mode signal MD1 is activated. The first pull-down driving circuit 23-1 pull-down drives the peripheral voltage VPERI using the first driving force after the boot-up operation is terminated, such that a voltage level of the peripheral voltage VPERI quickly reaches a target voltage level.

The second pull-down driving circuit 23-2 pull-down drives the peripheral voltage VPERI using a second driving force based on the power boot-up signal PWR-BUP and a second mode signal MD2. The second mode signal MD2 is activated to pull-down drive the peripheral voltage VPERI using the second driving force. The second pull-down driving circuit 23-2 pull-down drives the peripheral voltage VPERI using the second driving force during the driving time period after the boot-up operation is terminated and the power boot-up signal PWR-BUP is deactivated while the second mode signal MD2 is activated. The second driving force is greater than the first driving force in this example. The second pull-down driving circuit 23-2 pull-down drives the peripheral voltage VPERI using the second driving force after the boot-up operation is terminated, such that the voltage level of the peripheral voltage VPERI reaches the target voltage level more quickly than when driven by the first pull-down driving circuit 23-1.

Each of the peripheral voltage control circuits 135-2 to 135-12, for example, such as shown in FIG. 2, may include a configuration for pull-up driving and a plurality of configurations for pull-down driving the peripheral voltage VPERI generated from each of the peripheral voltage generation circuits 133-2 to 133-12 similar to the peripheral voltage control circuit 135-1A. The quantity of configurations for pull-down driving may be three or more, depending on the embodiment.

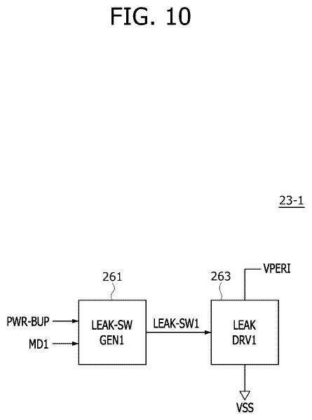

FIG. 10 illustrates a first pull-down driving circuit 23-1 according to an embodiment of the present disclosure, for example, as shown in FIG. 5.

As shown in FIG. 10, the first pull-down driving circuit 23-1 includes a first leakage switching signal generation circuit (LEAK SW GEN1) 261 and a first leakage driving circuit (LEAK DRV1) 263.

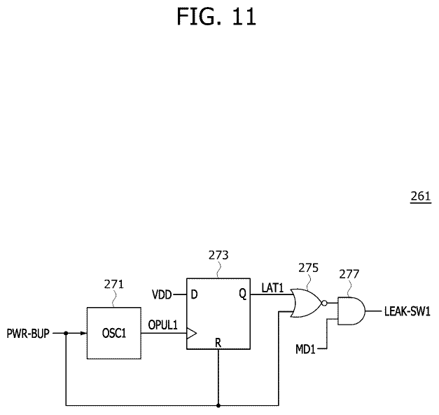

The first leakage switching signal generation circuit 261 generates a first leakage switching signal LEAK-SW1 to pull-down drive a peripheral voltage VPERI using a first driving force during a driving time period after a boot-up operation is terminated based on a power boot-up signal PWR-BUP and a first mode signal MD1. The first leakage switching signal generation circuit 261 receives the power boot-up signal PWR-BUP deactivated at a logic low level after the boot-up operation is terminated, and generates an oscillating pulse, for example, OPUL1 in FIG. 11, which is a cyclic signal. The first leakage switching signal generation circuit 261 generates the first leakage switching signal LEAK-SW1 that is activated at a logic high level to pull-down drive the peripheral voltage VPERI using the first driving force during the driving time period based on a cycle of the oscillating pulse.

The first leakage driving circuit 263 is electrically connected to the first leakage switching signal generation circuit 261 and receives the first leakage switching signal LEAK-SW1 from the first leakage switching signal generation circuit 261. The first leakage driving circuit 243 pull-down drives the peripheral voltage VPERI using the first driving force based on the first leakage switching signal LEAK-SW1. The first leakage driving circuit 243 receives the first leakage switching signal LEAK-SW1 that is activated during the driving time period after the boot-up operation is terminated and pull-down drives the peripheral voltage VPERI using the first driving force.

FIG. 11 illustrates an embodiment of a first leakage switching signal generation circuit 261 according to an embodiment of the present disclosure, for example, as shown in FIG. 10.

As shown in FIG. 11, the first leakage switching signal generation circuit 261 includes a first oscillator (OSC1) 271, a first latch 273, a first logic device 275, and a second logic device 277.

The first oscillator 271 generates a first oscillating pulse OPUL1 based on a power boot-up signal PWR-BUP. The first oscillator 271 generates the first oscillating pulse OPUL1 when the power boot-up signal PWR-BUP is received, which power boot-up signal PWR-BUP is deactivated after the boot-up operation is terminated. The first oscillating pulse OPUL1 is a cyclic signal, and a cycle of the first oscillating pulse OPUL1 is, for example, 1 ms, and the present disclosure is not limited to this example.

The first latch 273 is electrically connected to the first oscillator 271 and receives the first oscillating pulse OPUL1 from the first oscillator 271. The latch 273 generates a first latch signal LAT1 that is activated when the first oscillating pulse OPUL1 is generated. The first latch 273 latches a power supply voltage VDD when the first oscillating pulse OPUL1 is a logic high level at a time when the driving time period elapses after the boot-up operation is terminated, thereby generating the first latch signal LAT1 activated at a logic high level. The first latch 273 initializes the first latch signal LAT1 based on the power boot-up signal PWR-BUP. The first latch 273 initializes the first latch signal LAT1 at a logic low level when the power boot-up signal PWR-BUP, activated at a logic high level, is received during a time period during which the boot-up operation is performed from a time when the power supply voltage VDD reaches a preset voltage level.

The first logic device 275 is electrically connected to the first latch 273 and receives the first latch signal LAT1 from the first latch 273. The first logic device 275 receives the first latch signal LAT1 and the power boot-up signal PWR-BUP and performs a NOR operation. The second logic device 277 is electrically connected to the first logic device 275 and receives an output signal of the first logic device 275. The second logic device 277 performs an AND operation on the output signal of the first logic device 275 and a first mode signal MD1 to generate the first leakage switching signal LEAK-SW1. The second logic device 277 receives the first latch signal LAT1 and the power boot-up signal PWR-BUP that are both deactivated at a logic low level to generate the first leakage switching signal LEAK-SW1 that is activated at a logic high level, during the driving time period after the boot-up operation is terminated while the first mode signal MD1 is activated.

When the power boot-up signal PWR-BUP that is activated at a logic high level is received during the time period in which the boot-up operation is performed from the time when the power supply voltage VDD reaches a preset voltage level, the first logic device 273 initializes the first latch signal LAT1 at a logic low level, the first logic device 275 outputs a signal at a logic low level, and the second logic device 277 generates the first leakage switching signal LEAK-SW1 that is deactivated at a logic low level. After the boot-up operation is terminated and the power boot-up signal PWR-BUP deactivated at a logic low level is received, the first oscillator 271 generates the first oscillating pulse OPUL1. During the driving time period that is a time period after the boot-up operation is terminated to a time when the first oscillating pulse OPUL1 is generated at a logic high level, the first latch signal LAT1 is maintained at a logic low level and the power boot-up signal PWR-BUP is maintained deactivated at a logic low level. Accordingly, the first logic device 275 outputs a signal at a logic high level, and the second logic device 277 generates the first leakage switching signal LEAK-SW1 activated at a logic high level. When the first oscillating pulse OPUL1 is generated at a logic high level and the driving time period ends, the first latch 273 latches the power supply voltage VDD to generate the first latch signal LAT1 at a logic high level. Accordingly, the first logic device 275 outputs a signal at a logic low level, and the second logic device 277 generates the first leakage switching signal LEAK-SW1 deactivated at a logic low level. The first leakage switching signal generation circuit 261 receives the power boot-up signal PWR-BUP that is deactivated after the boot-up operation is terminated to generate the first oscillating pulse OPUL1 that is a cyclic signal and generates the first leakage switching signal LEAK-SW1 activated at a logic high level to pull-down drive the peripheral voltage VPERI using the first driving force during a driving time period set based on the cycle of the first oscillating pulse OPUL1 while the first mode signal MD1 is activated.

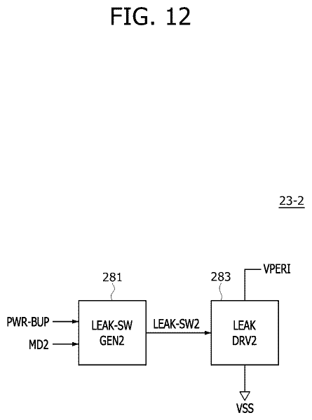

FIG. 12 illustrates an embodiment of a second pull-down driving circuit 23-2 according to an embodiment of the present disclosure, for example, as shown in FIG. 5.

As shown in FIG. 12, the second pull-down driving circuit 23-2 includes a second leakage switching signal generation circuit (LEAK-SW GEN2) 281 and a second leakage driving circuit (LEAK DRV2) 283.

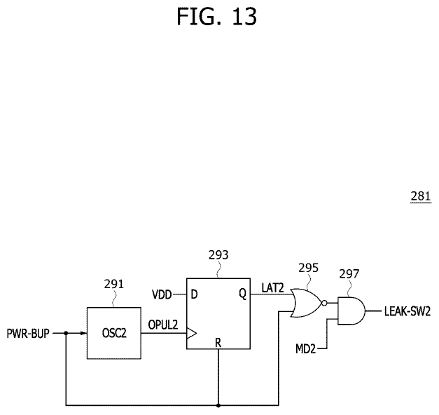

The second leakage switching signal generation circuit 281 generates a second leakage switching signal LEAK-SW2 to pull-down drive a peripheral voltage VPERI using a second driving force during a driving time period after a boot-up operation is terminated based on a power boot-up signal PWR-BUP and a second mode signal MD2. The second leakage switching signal generation circuit 281 receives the power boot-up signal PWR-BUP that is deactivated at a logic low level after the boot-up operation is terminated and generates an oscillating pulse, for example, OPUL2 of FIG. 13, which is a cyclic signal. The second leakage switching signal generation circuit 281 generates a second leakage switching signal LEAK-SW2 that is activated at a logic high level to pull-down drive the peripheral voltage VPERI using the second driving force during the driving time period set based on the cycle or frequency of the oscillating pulse.

The second leakage driving circuit 283 is electrically connected to the second leakage switching signal generation circuit 281 and receives the second leakage switching signal LEAK-SW2 from the second leakage switching signal generation circuit 281. The second leakage driving circuit 283 pull-down drives the peripheral voltage VPERI using the second driving force based on the second leakage switching signal LEAK-SW2. The second leakage driving circuit 283 receives the second leakage switching signal LEAK-SW2 that is activated during the driving time period after the boot-up operation is terminated, and pull-down drives the peripheral voltage VPERI using the second driving force.

FIG. 13 illustrates an embodiment of a second leakage switching signal generation circuit 281 according to an embodiment of the present disclosure, for example, as shown in FIG. 12.

As shown in FIG. 13, the second leakage switching signal generation circuit 281 includes a second oscillator (OSC2) 291, a second latch 293, a third logic device 295, and a fourth logic device 297.

The second oscillator 291 generates a second oscillating pulse OPUL2 based on a power boot-up signal PWR-BUP. The second oscillator 291 generates the second oscillating pulse OPUL2 when the power boot-up signal PWR-BUP is received, which is deactivated at a logic low level after the boot-up operation is terminated. The second oscillating pulse OPUL2 is a cyclic signal, and a cycle of the second oscillating pulse OPUL2 is, for example, 1 ms, and the present disclosure is not limited to this example.

The second latch 293 is electrically connected to the second oscillator 291 and receives the second oscillating pulse OPUL2 from the second oscillator 291. The second latch 293 generates a second latch signal LAT2 that is activated at a logic high level when the second oscillating pulse OPUL2 is generated. The second latch 293 latches the power supply voltage VDD when the second oscillating pulse OPUL2 is at a logic high level at a time when the driving time period elapses after the boot-up operation is terminated, thereby generating the second latch signal LAT2 activated at a logic high level. The second latch 293 initializes the second latch signal LAT2 based on the power boot-up signal PWR-BUP. The second latch 293 initializes the second latch signal LAT2 at a logic low level when the power boot-up signal PWR-BUP activated at a logic high level is received during the time period during which the boot-up operation is performed from a time when the power supply voltage VDD reaches a preset voltage level.

The third logic device 295 is electrically connected to the second latch 293 and receives the second latch signal LAT2 from the second latch 293. The third logic device 295 receives the second latch signal LAT2 and the power boot-up signal PWR-BUP and performs a NOR operation. The fourth logic device 297 is electrically connected to the third logic device 295 and receives an output signal of the third logic device 295. The fourth logic device 297 performs an AND operation on the output signal of the third logic device 295 and a second mode signal MD2 to generate a second leakage switching signal LEAK-SW2. During the driving time period after the boot-up operation is terminated while the second mode signal MD2 is activated at a logic high level, the fourth logic device 297 receives the second latch signal LAT2 and the power boot-up signal PWR-BUP that are both deactivated at a logic low level and generates the second leakage switching signal LEAK-SW2 that is activated at a logic high level.

When the power boot-up signal PWR-BUP activated at a logic high level is received during a time period during which the boot-up operation is performed from the time when the power supply voltage VDD reaches a preset voltage level, the second latch 293 initializes the second latch signal LAT2 at a logic low level, the third logic device 295 outputs a signal of a logic low level, and the fourth logic device 297 generates the second leakage switching signal LEAK-SW2 deactivated at a logic low level. After the boot-up operation is terminated and the power boot-up signal PWR-BUP deactivated at a logic low level is received, the second oscillator 291 generates the second oscillating pulse OPUL2. During the driving time period after the boot-up operation is terminated to a time when the second oscillating pulse OPUL2 is generated at a logic high level, the second latch signal LAT2 is maintained at the logic low level, and the power boot-up signal PWR-BUP is maintained in a deactivated state at the logic low level. Accordingly, the third logic device 295 outputs a signal of a logic high level, and the fourth logic device 297 generates the second leakage switching signal LEAK-SW2 activated at a logic high level. At the time when the second oscillating pulse OPUL2 is generated at a logic high level and the driving time period ends, the second latch 293 latches the power supply voltage VDD to generate the second latch signal LAT2 at a logic high level. Accordingly, the third logic device 295 outputs a signal at a logic low level, and the fourth logic device 297 generates the second leakage switching signal LEAK-SW2 deactivated at a logic low level. The second leakage switching signal generation circuit 291 receives the power boot-up signal PWR-BUP that is deactivated at a logic low level after the boot-up operation is terminated to generate the second oscillating pulse OPUL2 that is a cyclic signal, and generates the second leakage switching signal LEAK-SW2 that is activated at a logic high level to pull-down drive the peripheral voltage VPERI using a second driving force during a driving time period based on the cycle of the second oscillating pulse OPUL2 while the second mode signal MD2 is activated.

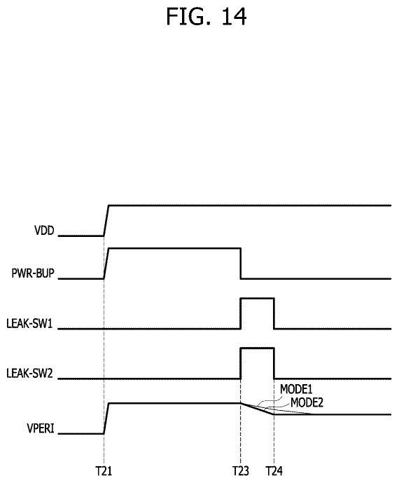

FIG. 14 is a timing diagram illustrating operation of a peripheral voltage control circuit 135-1A according to an embodiment of the present disclosure, for example, as shown in FIG. 9.

At time T21, when a power supply voltage VDD is applied to a memory device 17, for example, as shown in FIG. 1, a voltage level of the power boot-up signal PWR-BUP rises together with the power supply voltage VDD. The power boot-up signal PWR-BUP is activated at a logic high level when the power supply voltage VDD reaches a preset voltage level. A pull-up driving circuit 21 of FIG. 9 receives the power boot-up signal PWR-BUP activated at a logic high level and pull-up drives the peripheral voltage VPERI to the power supply voltage VDD.

After the boot-up operation is terminated at time T23, the power boot-up signal PWR-BUP is deactivated at a logic low level. When a first mode signal MD1 is activated at a logic high level during a driving time period T23 to T24 after the boot-up operation is terminated, a first leakage switching signal LEAK-SW1 is generated activated at a logic high level, and when a second mode signal MD2 is activated at a logic high level, a second leakage switching signal LEAK-SW2 is generated activated at a logic high level. In a first mode MODE1 in which the first mode signal MD1 is activated, the peripheral voltage VPERI is pull-down driven using a first driving force during the driving time period T23 to T24. In a second mode MODE2 in which the second mode signal MD2 is activated at a logic high level, the peripheral voltage VPERI is pull-down driven using a second driving force during the driving time period T23 to T24. The peripheral voltage VPERI is driven using the driving force greater in the second mode MODE2 than the driving force in the first mode MODE1. Accordingly, the peripheral voltage VPERI reaches a target voltage level more quickly in the second MODE2 than in the first mode MODE2.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. The scope of the present disclosure is not limited to the descriptions, and all distinctive features within an equivalent scope should be construed as included in the present disclosure. All changes within the meaning and range of equivalency of the claims are included within their scope.

What is claimed is:

1. A memory system comprising:
an interposer disposed over a substrate; and
a memory device and a processor disposed over the interposer and connected through wiring inside the interposer;
wherein the memory device comprises a base die and a plurality of core dies stacked over the interposer;
wherein the base die operates at an input/output power voltage;
wherein each of the plurality of core dies receives a power supply voltage through the base die to generate a peripheral voltage at a lower voltage level than the power supply voltage and operates at the peripheral voltage.

2. The memory system of claim 1,
wherein each of the plurality of core dies comprises a peripheral voltage control circuit;
wherein the peripheral voltage control circuit is configured to pull-up drive the peripheral voltage according to the power supply voltage until a boot-up operation is terminated; and
wherein the peripheral voltage control circuit is configured to pull-down drive the peripheral voltage at a target voltage level during a driving time period after the boot-up operation is terminated.

3. The memory system of claim 2, wherein the peripheral voltage control circuit comprises:
a pull-up driving circuit configured to pull-up drive the peripheral voltage based on a power boot-up signal; and
a pull-down driving circuit configured to pull-down drive the peripheral voltage based on the power boot-up signal.

4. The memory system of claim 3,
wherein the pull-up driving circuit is configured to receive the power boot-up signal that is activated according to the power supply voltage during a power-up time period, and
wherein the power boot-up signal is deactivated in synchronization with the time when the boot-up operation is terminated.

5. The memory system of claim 3, wherein the pull-up driving circuit is configured to drive the peripheral voltage to the power supply voltage when the power boot-up signal is activated.

6. The memory system of claim 3, wherein the pull-down driving circuit is configured to drive the peripheral voltage to a ground voltage during the driving time period from the time when the power boot-up signal is deactivated.

7. The memory system of claim 3, wherein the pull-down driving circuit comprises:
a leakage switching signal generation circuit configured to generate a leakage switching signal based on the power boot-up signal; and
a leakage driving circuit configured to pull-down drive the peripheral voltage based on the leakage switching signal.

8. The memory system of claim 7, wherein the leakage switching signal generation circuit comprises:
an oscillator configured to generate an oscillating pulse after the boot-up operation is terminated and the power boot-up signal is deactivated;
a latch configured to latch a power supply voltage when the oscillating pulse is generated and generate a latch signal; and
a logic device configured to generate the leakage switching signal to pull-down drive the peripheral voltage during the driving time period based on the latch signal and the power boot-up signal.

9. The memory system of claim 7, wherein the leakage driving circuit comprises a driving device configured to turn on based on the leakage switching signal to pull-down drive the peripheral voltage to a ground voltage.

10. The memory system of claim 1, wherein the peripheral voltage control circuit comprises:
a pull-up driving circuit configured to pull-up drive the peripheral voltage based on a power boot-up signal;
a first pull-down driving circuit configured to pull-down drive the peripheral voltage using a first driving force based on the power boot-up signal when a first mode signal is activated; and
a second pull-down driving circuit configured to pull-down drive the peripheral voltage using a second driving force based on the power boot-up signal when a second mode signal is activated.

11. The memory system of claim 10, wherein the peripheral voltage control circuit is configured to receive the power boot-up signal that is activated according to the power supply voltage during the power-up time period and deactivated in synchronization with a time when the boot-up operation ends.

12. The memory system of claim 10, wherein the first pull-down driving circuit comprises:
a first leakage switching signal generation circuit configured to generate a first leakage switching signal based on the power boot-up signal; and
a first leakage driving circuit configured to pull-down drive the peripheral voltage using the first driving force based on the first leakage switching signal.

13. The memory system of claim 12, wherein the first leakage switching signal generation circuit comprises:
a first oscillator configured to generate a first oscillating pulse after the boot-up operation is terminated and the power boot-up signal is deactivated;
a first latch configured to latch a power supply voltage when the first oscillating pulse is generated to generate a first latch signal;
a first logic device configured to perform a first logical operation based on the first latch signal and the power boot-up signal; and
a second logic device configured to generate the first leakage switching signal to pull-down drive the peripheral voltage using the first driving force during the driving time period based on an output signal of the first logic device when the first mode signal is activated.

14. The memory system of claim 10, wherein the second pull-down driving circuit comprises:
a second leakage switching signal generation circuit configured to generate a second leakage switching signal based on the power boot-up signal; and
a second leakage driving circuit configured to pull-down drive the peripheral voltage using the second driving force based on the second leakage switching signal.

15. A memory device comprising:
a base die configured to receive and operate at an input/output power voltage; and
a plurality of core dies stacked over the base die;
wherein each of the plurality of core dies receives a power supply voltage through the base die to generate a peripheral voltage at a lower voltage level than the input/output power voltage and operates at the peripheral voltage.

16. The memory device of claim 15, wherein each of the plurality of core dies comprises a peripheral voltage control circuit;
wherein the peripheral voltage control circuit is configured to pull-down drive the peripheral voltage at a target voltage level during a driving time period after the boot-up operation is terminated; and
wherein the peripheral voltage control circuit is configured to receive a power boot-up signal that is activated according to a power supply voltage during a power-up time period and deactivated in synchronization with the time when the boot-up operation is terminated.

17. The memory device of claim 16, wherein the peripheral voltage control circuit comprises:
a pull-up driving circuit configured to pull-up drive the peripheral voltage based on the power boot-up signal; and
a pull-down driving circuit configured to pull-down drive the peripheral voltage based on the power boot-up signal.

18. The memory device of claim 17, wherein the pull-up driving circuit is configured to drive the peripheral voltage to the power supply voltage when the power boot-up signal is activated.

19. The memory device of claim 17, wherein the pull-down driving circuit comprises:
a leakage switching signal generation circuit configured to generate a leakage switching signal based on the power boot-up signal; and
a leakage driving circuit configured to pull-down drive the peripheral voltage based on the leakage switching signal.

20. The memory device of claim 16, wherein the peripheral voltage control circuit comprises:
a pull-up driving circuit configured to pull-up drive the peripheral voltage based on the power boot-up signal;
a first pull-down driving circuit configured to pull-down drive the peripheral voltage using a first driving force based on the power boot-up signal when a first mode signal is activated; and
a second pull-down driving circuit configured to pull-down drive the peripheral voltage using a second driving force based on the power boot-up signal when a second mode signal is activated.

21. A method of controlling an operating voltage, the method comprising:
pull-up driving a peripheral voltage supplied to a core die to a power supply voltage when a power boot-up signal is activated; and
pull-down driving the peripheral voltage to a ground voltage when the power boot-up signal is deactivated;
wherein the power boot-up signal is activated according to a power supply voltage until a boot-up operation is terminated; and
wherein the power boot-up signal is deactivated in synchronization with a time when the boot-up operation is terminated.

22. The method of claim 21, wherein pull-down driving the peripheral voltage comprises:
generating an oscillating pulse after the boot-up operation is terminated; and
establishing the driving time period based on the oscillating pulse.

23. The method of claim 22, wherein pull-down driving the peripheral voltage further comprises:
generating a leakage switching signal activated during the driving time period; and
pull-down driving the peripheral voltage based on the leakage switching signal.

24. The method of claim 21, wherein pull-down driving the peripheral voltage comprises:
pull-down driving the peripheral voltage using a first driving force when a first mode signal is activated during a driving time period after the boot-up operation is terminated; and
pull-down driving the peripheral voltage using a second driving force when a second mode signal is activated during the driving time period after the boot-up operation is terminated.

25. The method of claim 21, wherein the second driving force is greater than the first driving force.

26. A memory device comprising:
a core die configured to comprise a plurality of peripheral voltage control circuits;
wherein each of peripheral voltage control circuits is configured to pull-up drive and pull-down drive to generate a peripheral voltage;
wherein the core die operates at the peripheral voltage; and
wherein the core die receives a power supply voltage and generates the peripheral voltage at a lower voltage level than the power supply voltage.

27. The memory device of claim 26,
wherein the peripheral voltage control circuit is configured to pull up drive the peripheral voltage according to the power supply voltage until a boot up operation is terminated; and
wherein the peripheral voltage control circuit is configured to pull down drive the peripheral voltage at a target voltage level during a driving time period after the boot up operation is terminated.
